(19) United States
(12) Patent Application Publication
(10) Pub. No.: US 2025/0200241 A1
(43) Pub. Date: Jun. 19, 2025

(54) LITHOGRAPHY SIMULATION METHOD AND OPTICAL PROXIMITY EFFECT CORRECTION METHOD

(71) Applicant: Kioxia Corporation, Tokyo (JP)

(72) Inventor: Shoji MIMOTOGI, Yokohama Kanagawa (JP)

(73) Assignee: Kioxia Corporation, Tokyo (JP)

(21) Appl. No.: 18/883,145

(22) Filed: Sep. 12, 2024

(30) Foreign Application Priority Data
Dec. 18, 2023 (JP) 2023-213308

(51) Int. Cl. G06F 30/17; G03F 1/36

(52) U.S. Cl. CPC G06F 30/17; G03F 1/36

(57) ABSTRACT

A lithography simulation method according to the present embodiment includes acquiring a mask shape to be transferred from a mask substrate to a wafer substrate using a projection exposure apparatus. The lithography simulation method also includes acquiring a control point on a contour figure included in the mask shape, a function form of a polynomial parameterization, and an order of the function form. The lithography simulation method also includes Fourier-transforming the contour figure using the polynomial parameterization based on the control point, the function form, and the order to predict a resist pattern.

### CROSS REFERENCE TO RELATED APPLICATIONS

This application is based upon and claims the benefit of priority from the prior Japanese Patent Application No. 2023-213308, filed on Dec. 18, 2023, the entire contents of which are incorporated herein by reference.

### FIELD

The embodiments of the present invention relate to a lithography simulation method and an optical proximity effect correction method.

### BACKGROUND

While a circuit structure of a semiconductor memory has been increasingly multilayered with a change from planar to three-dimensional structure for the purpose of an increase in capacity, minification in a planar direction has still been going on in order to cut costs. The use of extreme ultraviolet light enables minification in the planar direction but the costs are considerably high. Accordingly, it is necessary to extend the life of immersion lithography exposure that uses an argon fluoride laser as a light source. A typical technology using immersion lithography exposure for minification in the planar direction is a technology called inverse lithography, in which a mask shape for obtaining a desired resist shape on a wafer is to be obtained by solving an inverse problem. A mask shape obtained by inverse lithography is usually a curved and complicated shape. However, since it is difficult to simulate a mask shape represented by a curve, the complicated curve is approximated by a straight line to perform a simulation. Thus, in order to reduce an error resulting from approximating a curve by a straight line, it is necessary to finely divide the straight line to reduce a difference from the curve and, accordingly, there is a concern that the amount of data is excessively increased.

### BRIEF DESCRIPTION OF THE DRAWINGS

FIG. 1 is a diagram illustrating an example of a method of manufacturing a semiconductor apparatus according to a first embodiment;

FIG. 2 is a diagram illustrating an example of a lithography simulation method according to the first embodiment;

FIG. 3A illustrates an example of a figure surrounded by a curve;

FIG. 3B illustrates an example of a figure represented by dividing the figure illustrated in FIG. 3A into straight lines;

FIG. 4 is a diagram illustrating an example of a domain surrounded by straight lines and coordinates according to a comparative example;

FIG. 5 is a diagram illustrating an example of a domain surrounded by a curve and a closed curve of a boundary according to the first embodiment;

FIG. 6 is a diagram illustrating an example of a parametric representation of the domain surrounded by the curve according to the first embodiment;

FIG. 7 is a graph showing an example of a result of the Fourier transform of a circle with a radius “a”; and

FIG. 8 is a diagram illustrating an example of a displayed content on a display device.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A lithography simulation method according to the present embodiment includes acquiring a mask shape to be transferred from a mask substrate to a wafer substrate using a projection exposure apparatus. The lithography simulation method also includes acquiring a control point on a contour figure included in the mask shape, a function form of a polynomial parameterization, and an order of the function form. The lithography simulation method also includes Fourier-transforming the contour figure using the polynomial parameterization based on the control point, the function form, and the order to predict a resist pattern.

### First Embodiment

In a lithography process of a semiconductor, even if designed pattern arrangement and shape are directly produced as mask arrangement and shape, a resist shape on a wafer transferred via an exposure apparatus fails to become a desired shape through an optical proximity effect. Accordingly, a correction called optical proximity effect correction is to be performed to cause the resist shape on the wafer to become the desired shape. With a recent progress in minimization, there is a demand for arranging a Sub-resolution Assist Feature (SRAF), which is not to be resolved on a wafer, for the optical proximity effect correction in order to not only obtain a desired shape but also make the shape unlikely to vary with respect to a variation in a wafer process. Further, with the progress in minimization, there is a demand for representing a mask shape not by a simple rectangle but by a curve in order to further enhance the above-described robustness.

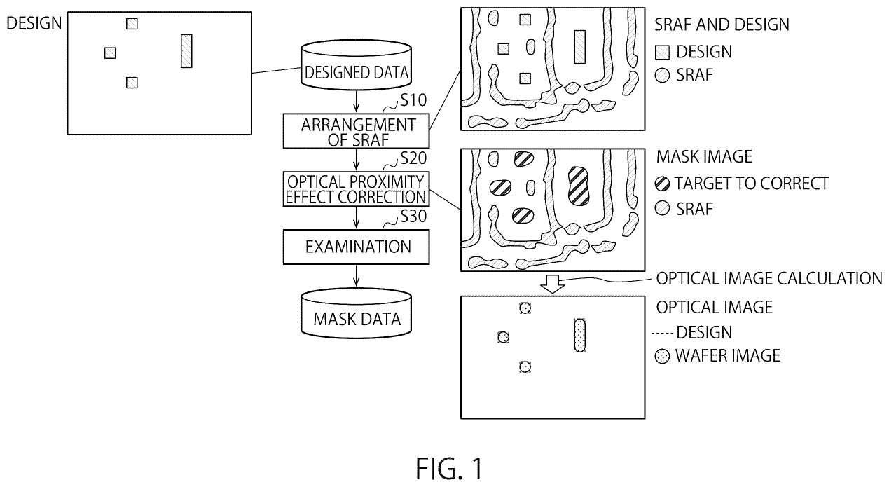

FIG. 1 is a diagram illustrating an example of a method of manufacturing a semiconductor apparatus according to a first embodiment. A middle of the FIG. 1 illustrates a flowchart to obtain a mask shape from a designed pattern.

First, designed data is inputted and a SRAF is generated in the designed data (S10). The SRAF may be generated by an inverse lithography approach or generated in accordance with a predetermined rule.

Next, optical proximity effect correction is performed (S20). The optical proximity effect correction is a process in which in a case where a result of lithography simulation of transfer to a wafer substrate differs from a desired shape, the pattern is corrected and the lithography simulation is again performed. The lithography simulation method is included in optical image calculation referred to in FIG. 1.

Next, examination is performed (S30). A shape of a resist pattern on a wafer is obtained by inputting, as data regarding the mask shape, layout data including a combination of the designed pattern subjected to the optical proximity effect correction and a SRAF pattern to a lithography simulator (written as “OPTICAL IMAGE CALCULATION” in FIG. 1).

As described above, if the shape of the designed pattern is unchanged, it is not possible to obtain the desired shape on the wafer through the optical proximity effect. Accordingly, the shape of the designed pattern is deformed so that the resist shape on the wafer becomes the desired shape and the deformation of the designed pattern and the lithography simulation are repeated until the resist shape on the wafer becomes the desired shape. After confirmed to become the desired shape by performing the lithography simulation, a combination of the shape after a final deformation and the SRAF is to be sent to a mask manufacturing process. A mask shape to be subjected to the lithography simulation at this time is represented by a curve. However, the fact that the mask shape is represented by a curve leads to concerns regarding the lithography simulation in some cases. The concerns will be described later.

Next, description will be made on an optical image calculation flow (the lithography simulation method) included in Step S20.

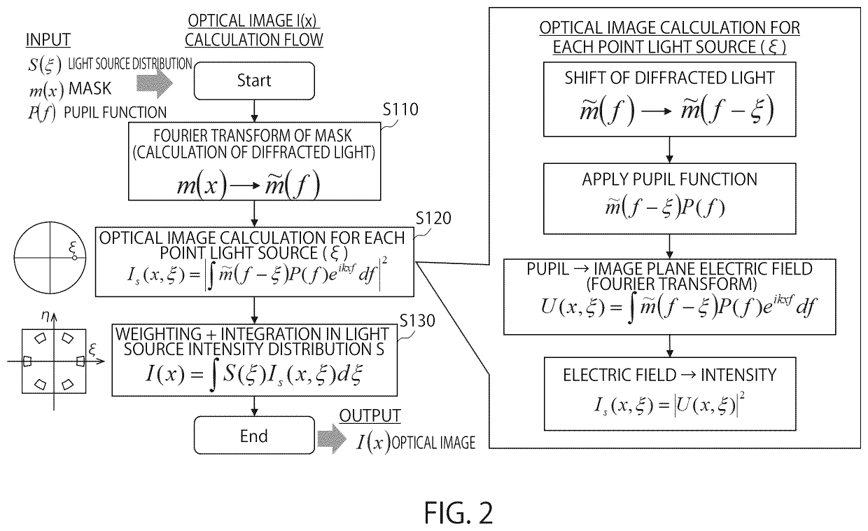

FIG. 2 is a diagram illustrating an example of the lithography simulation method according to the first embodiment.

Conditions (a light source shape S(ξ) and a pupil function P(f)) regarding exposure in an exposure process and mask shape data m(x) are to be inputted and an optical image I(x) is to be outputted after calculation.

First, the Fourier transform of the mask shape data m(x) is performed (S110). The light source shape S(ξ) is discretized and considered as a set of point light sources. An optical image relative to one of the point light sources is obtained.

Next, optical image calculation is performed for each point light source (ξ) (S120).

Next, weighting and integration in a light source intensity distribution S are performed (S130). That is to say, integration is performed to obtain a sum of the optical images at the respective point light sources.

Next, description will be made on the Fourier transform included in Step S110 and a mask shape having a curved shape.

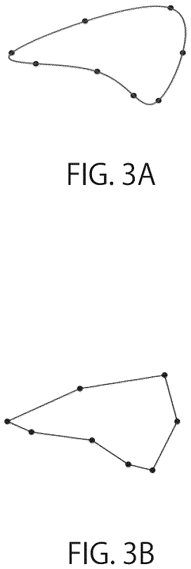

FIG. 3A illustrates an example of a figure surrounded by a curve. FIG. 3B illustrates an example of a figure represented by dividing the figure illustrated in FIG. 3A into straight lines.

In a case where the figure is divided into eight straight lines as illustrated in FIG. 3B, a deviation from the original curve is large and thus a favorable approximation is unobtainable unless the number of divisions is increased. An increase in the number of divisions is disadvantageous in that the amount of data is increased. This is one of the concerns regarding the lithography simulation of a mask shape represented by a curve. Accordingly, for example, a cubic Bezier curve is used, which makes it possible to represent the figure surrounded by a curve in FIG. 3A by eight control points. This can reduce an increase in the amount of data.

In a case where a mask shape represented by a Bezier curve or the like is to be subjected to the lithography simulation, only a figure surrounded by straight lines as in FIG. 3B is usually handleable. Accordingly, in the present embodiment, the curved figure is to be directly processed without being divided into straight lines. Specifically, the curve is parametrically represented as a Bezier curve, a Spline curve, or the like and subjected to the Fourier transform.

Next, description will be made on the Fourier transform using the parametric representation.

A domain surrounded by a curve or straight lines in an x-y plane is denoted by “D.” “D” provides a mask shape. The Fourier transform of the mask shape means a calculation of (Expression 1).

$$\hat{m} ( {k}_{x} , {k}_{y} ) = \frac{1}{2 π} \int {\int }_{D} dxdy \cdot {e}^{- i ( {k}_{x} x + {k}_{y} y )} \qquad ( Expression 1 )$$

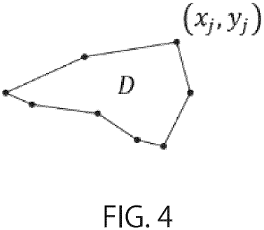

FIG. 4 is a diagram illustrating an example of the domain D surrounded by straight lines and coordinates according to a comparative example.

As the comparative example, the mask shape represented by the domain D surrounded by the straight lines as in FIG. 4 is subjected to the Fourier transform. With the assumption that the coordinates of the end points of the straight lines are (xⱼ, yⱼ) (“j”=0, 1, . . . , N−1), (Expression 4) is derived by setting up (Expression 1) using “aⱼ” and “S_{j, j+1}” defined by (Expression 2) and (Expression 3).

$${a}_{j} = {k}_{x} {x}_{j} + {k}_{y} {y}_{j} \qquad ( Expression 2 )$$

$${S}_{j , j + 1} = \frac{1}{2} ( {x}_{j} {y}_{j + 1} - {y}_{j} {x}_{j + 1} ) \qquad ( Expression 3 )$$

$$\hat{m} ( {k}_{x} , {k}_{y} ) = \frac{2 {S}_{j , j + 1}}{{a}_{j + 1} - {a}_{j}} ( \frac{1 - {e}^{- {ia}_{j + 1}}}{{a}_{j + 1}} - \frac{1 - {e}^{- {ia}_{j}}}{{a}_{j}} ) \qquad ( Expression 4 )$$

Next, description will be made on, as the present embodiment, a method in which a curve is to be handled as the curve.

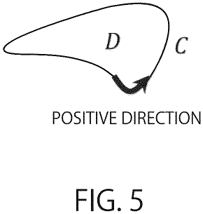

FIG. 5 is a diagram illustrating an example of the domain D surrounded by a curve and a closed curve C of a boundary according to the first embodiment.

In order to perform a double integration in the domain D of (Expression 1), the closed curve C, which determines the boundary of the domain D, as in FIG. 5 is assumed. With the assumption that P (x, y) and Q (x, y) are continuous within the domain D and differentiation thereof is possible, (Expression 5) holds by Green's theorem.

$$\int {\int }_{D} dxdy ( \frac{\partial Q}{\partial x} - \frac{\partial P}{\partial y} ) = {∮}_{C} ( Pdx + Qdy ) \qquad ( Expression 5 )$$

It is possible to simplify the calculation by using Green's theorem to replace the double integration in the domain D with a single integration on the closed curve C of the boundary. At this time, it is assumed that the direction of the integration on the closed curve C is an anticlockwise direction illustrated in FIG. 5.

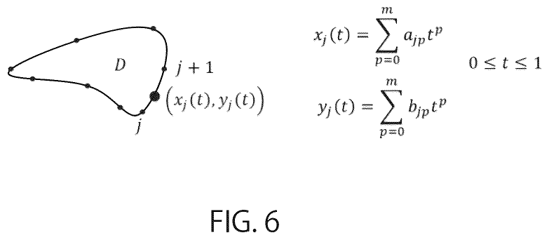

FIG. 6 is a diagram illustrating an example of a parametric representation of the domain D surrounded by the curve according to the first embodiment.

With the assumption that the domain surrounded by the curve is denoted by D and a point on the curve is denoted by j (j=0, 1, . . . , N−1) in FIG. 6, a parametric representation such as a Bezier curve or a Spline curve is performed. The point j on the curve is referred to as control point and the coordinates thereof are assumed to be (xⱼ, yⱼ). A curve between the point j and a point (j+1) can be represented as (Expression 6) and (Expression 7). Here, “m” denotes the order of the curve, usually a natural number of up to 3.

$$\begin{matrix}{x}_{j} ( t ) = {\sum }_{p = 0}^{m} {a}_{jp} {t}^{p} & 0 \leq t \leq 1\end{matrix} \qquad ( Expression 6 )$$

$$\begin{matrix}{y}_{j} ( t ) = {\sum }_{p = 0}^{m} {b}_{jp} {t}^{p} & 0 \leq t \leq 1\end{matrix} \qquad ( Expression 7 )$$

The Fourier transform of the domain D is obtained from the parametric representation. Here, coefficients “aⱼₚ”, “bⱼₚ” of the parametric representation are as in Table 1 and Table 2. Table 1 shows a coefficient of “xⱼ” in the parametric representation. Table 2 shows a coefficient of “yⱼ” in the parametric representation.

TABLE 1

| | | aⱼ₀ | aⱼ₁ | aⱼ₂ | aⱼ₃ |
|---|---|---|---|---|---|
| Linear | 1st order | xⱼ | −xⱼ + xⱼ₊₁ | | |
| Spline | 2nd order | $\frac{{x}_{j - 1} + {x}_{j}}{2}$ | −xⱼ₋₁ + xⱼ | $\frac{{x}_{j - 1} - 2 {x}_{j} + {x}_{j + 1}}{2}$ | |
| | 3rd order | $\frac{{x}_{j - 1} + 4 {x}_{j} + {x}_{j + 1}}{6}$ | $\frac{- {x}_{j - 1} + {x}_{j + 1}}{2}$ | $\frac{{x}_{j - 1} - 2 {x}_{j} + {x}_{j + 1}}{2}$ | $\frac{- {x}_{j - 1} + 3 {x}_{j} - 3 {x}_{j + 1} + {x}_{j + 2}}{6}$ |
| Bezier | 3rd order | xⱼ₋₁ | −3xⱼ₋₁ + 3pⱼ₋₁ | 3xⱼ₋₁ − 6pⱼ₋₁ + 3rⱼ₋₁ | −xⱼ₋₁ + 3pⱼ₋₁ − 3rⱼ₋₁ + xⱼ |

TABLE 2

| | | bⱼ₀ | bⱼ₁ | bⱼ₂ | bⱼ₃ |
|---|---|---|---|---|---|
| Linear | 1st order | yⱼ | −yⱼ + yⱼ₊₁ | | |
| Spline | 2nd order | $\frac{{y}_{j - 1} + {y}_{j}}{2}$ | −yⱼ₋₁ + yⱼ | $\frac{{y}_{j - 1} - 2 {y}_{j} + {y}_{j + 1}}{2}$ | |
| | 3rd order | $\frac{{y}_{j - 1} + 4 {y}_{j} + {y}_{j + 1}}{6}$ | $\frac{- {y}_{j - 1} + {y}_{j + 1}}{2}$ | $\frac{{y}_{j - 1} - 2 {y}_{j} + {y}_{j + 1}}{2}$ | $\frac{- {y}_{j - 1} + 3 {y}_{j} - 3 {y}_{j + 1} + {y}_{j + 2}}{6}$ |
| Bezier | 3rd order | yⱼ₋₁ | −3yⱼ₋₁ + 3qⱼ₋₁ | 3yⱼ₋₁ − 6qⱼ₋₁ + 3sⱼ₋₁ | −yⱼ₋₁ + 3qⱼ₋₁ − 3sⱼ₋₁ + yⱼ |

In a case where a quadratic Spline curve is used as the parametric representation by way of example, a variable defined by (Expression 8) is used and the Fourier transform of the domain D can be represented as an imaginary error function (“erfi(u)”) as in (Expression 9).

$$\begin{matrix}{c}_{jp} = - i ( {k}_{x} {a}_{jp} + {k}_{y} {b}_{jp} ) \\ \begin{matrix}{u}_{0} = \frac{{c}_{i 1}}{2 \sqrt{{c}_{i 2}}} & {u}_{1} = \sqrt{{c}_{i 2}} + {u}_{0}\end{matrix} \\ {p}_{j} = \frac{- {c}_{j 2}^{2} + 3 {c}_{j 1} {c}_{j 3}}{3 {c}_{j 3}^{4 / 3}} \\ {d}_{j} = - i ( {c}_{j} - \frac{{b}_{j}^{2}}{4 {a}_{j}} )\end{matrix} \} \qquad ( Expression 8 )$$

$$( Expression 9 )$$

$$\hat{m} ( {k}_{x} , {k}_{y} ) {\sum }_{j = 0}^{N - 1} {\frac{1}{2 π \sqrt{- {ia}_{j}}} [ ( - \frac{{γ}_{j}}{{d}_{j}} u + \frac{{β}_{j}}{2} ) \frac{{e}^{{u}^{2} + {d}_{j}} - 1}{{u}^{2} + {d}_{j}} + \frac{\sqrt{π} {γ}_{j} {e}^{{d}_{j}}}{2 {d}_{j}} erfi ( u ) ]}_{{u}_{0}}^{{u}_{1}}$$

$$( {d}_{j} \neq 0 , {u}^{2} + {d}_{j} \neq 0 )$$

Further, in a case where a cubic Bezier curve is used as the parametric representation by way of another example, a variable defined by (Expression 10) is used and the Fourier transform of the domain D is represented by (Expression 11) and (Expression 12). Here, “mₖ” and “xₖ” in (Expression 12) denote a weight according to the Gauss-Legendre quadrature and a k-th solution providing an n-th order Legendre polynomial Pₙ(x)=1. As an example, a weight “mₖ” and a k-th solution “xₖ” for “n”=20 are shown in Table 3. Incidentally, it has been known that a value of “n” is settable as desired and there are values of “mₖ” and “xₖ”, which is in the form of a table, suitable according to the value of “n.”

$$\begin{matrix}{c}_{jp} = - i ( {k}_{x} {a}_{jp} + {k}_{y} {b}_{jp} ) \\ {p}_{j} = \frac{- {c}_{j 2}^{2} + 3 {c}_{j 1} {c}_{j 3}}{3 {c}_{j 3}^{4 / 3}} \\ {q}_{j} = \frac{2 {c}_{j 2}^{3}}{27 {c}_{j 3}^{2}} - \frac{{c}_{j 1} {c}_{j 2}}{3 {c}_{j 3}} + {c}_{j 0} \\ {β}_{j 0} = {b}_{j 1} + \frac{{b}_{j 3} {c}_{j 2}^{2}}{3 {c}_{j 3}^{2}} - \frac{2 {b}_{j 2} {c}_{j 2}}{3 {c}_{j 3}} \\ {β}_{j 1} = \frac{2 {b}_{j 2}}{{c}_{j 3}^{1 / 3}} - \frac{2 {b}_{j 3} {c}_{j 2}}{{c}_{j 3}^{4 / 3}} \\ {β}_{j 2} = \frac{3 {b}_{j 3}}{{c}_{j 3}^{2 / 3}} \\ {u}_{0} = \frac{{c}_{j 2}}{3 {c}_{j 3}^{2 / 3}} \\ {u}_{1} = {c}_{j 3}^{1 / 3} + {u}_{0}\end{matrix} \} \qquad ( Expression 10 )$$

$${f}_{j} ( u ) = \{ {β}_{j 1} u + ( {β}_{j 0} - \frac{{β}_{j 2}}{3} {p}_{i} ) \} {e}^{{u}^{3} + {p}_{j} u} \qquad ( Expression 11 )$$

$$\hat{m} ( {k}_{x} , {k}_{y} ) = - {\sum }_{j = 0}^{N - 1} \frac{1}{2 π \text{?}} \frac{\text{?}}{\text{?}} [ ( \frac{{β}_{j 2}}{3} e \text{?} ] \text{?} + \frac{\text{?} - \text{?}}{2} \sum \text{?} {m}_{k} {f}_{j} ( \frac{{u}_{1} - {u}_{0}}{2} {x}_{k} + \frac{{u}_{1} - {u}_{0}}{2} ) ) ( k \text{?} \neq 0 \text{?} {c}_{j 2} \neq 0 ) \qquad ( Expression 12 )$$

$$\text{?} \text{indicates text missing or illegible when filed}$$

TABLE 3

| k | xₖ | mₖ |
|---|---|---|
| 1 | −0.99313 | 0.017614 |
| 2 | −0.96397 | 0.040601 |
| 3 | −0.91223 | 0.062672 |
| 4 | −0.83912 | 0.083277 |
| 5 | −0.74633 | 0.10193 |
| 6 | −0.63605 | 0.118195 |
| 7 | −0.51087 | 0.131689 |
| 8 | −0.37371 | 0.142096 |
| 9 | −0.22779 | 0.149173 |
| 10 | −0.07653 | 0.152753 |
| 11 | 0.076527 | 0.152753 |
| 12 | 0.227786 | 0.149173 |
| 13 | 0.373706 | 0.142096 |
| 14 | 0.510867 | 0.131689 |
| 15 | 0.636054 | 0.118195 |
| 16 | 0.746332 | 0.10193 |
| 17 | 0.839117 | 0.083277 |
| 18 | 0.912234 | 0.062672 |
| 19 | 0.963972 | 0.040601 |
| 20 | 0.993129 | 0.017614 |

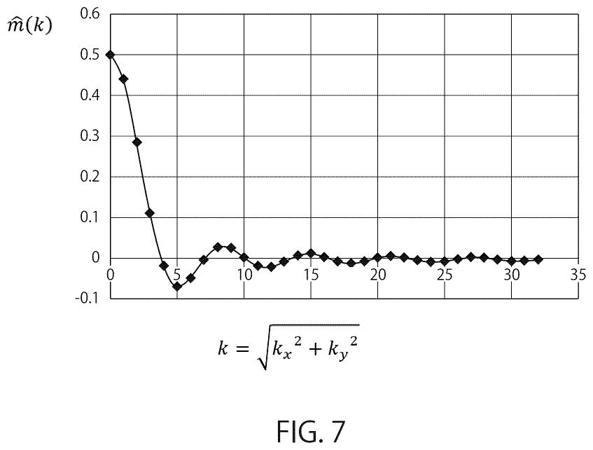

FIG. 7 is a graph showing an example of a result of the Fourier transform of a circle with a radius “a.” A dot in FIG. 7 represents a result of the Fourier transform of the circle with the radius “a”, in which a cubic Bezier curve is used as the parametric representation and the number of control points is eight. A solid line in FIG. 7 represents a result of the use of a Bessel function.

It has been found that a rigorous Fourier transform of the circle with the radius “a” can be represented by the Bessel function as in (Expression 13) by another method. As shown in FIG. 7, the result in which the Bessel function is used almost matches the result in which the cubic Bezier curve is used.

$$\begin{matrix}{J}_{n} ( x ) = {\sum }_{k = 0}^{∞} \frac{{( - 1 )}^{k}}{k ! ( k + n ) !} {( \frac{x}{2} )}^{2 k + n} \\ \hat{m} ( {k}_{x} , {k}_{y} ) = \frac{a}{k} {J}_{1} ( ak )\end{matrix} \} \qquad ( Expression 13 )$$

Moreover, although the integration of the function defined by (Expression 11) is performed by the Gauss-Legendre quadrature, the use of “n” according to a phase fluctuation in an integral interval defined by (Expression 14) further enhances accuracy. As long as “n” of the Gauss-Legendre quadrature is approximately three times or more of “M” represented by (Expression 14), a calculation with a significantly high accuracy is possible. That is to say, the order (“n”) of the Legendre polynomial of the Gauss-Legendre quadrature is set in accordance with the phase variation of an integrand in the integral interval. It should be noted that “M” is to be computed by substituting the value of (Expression 11) into (Expression 14).

$$M = \frac{1}{2 π} \{ arg ( {f}_{i} ( {u}_{1} ) ) - arg ( {f}_{i} ( {u}_{0} ) ) \} \qquad ( Expression 14 )$$

Thus, in performing the Fourier transform of a figure surrounded by a curve, a high-speed and high-accuracy calculation is made possible by parametrically representing the curve, transforming a double integration into a single integration by Green's theorem, and, even though a function is not integrable, applying the Gauss-Legendre quadrature.

As described above, according to the first embodiment, a mask shape to be transferred from a mask substrate to a wafer substrate using a projection exposure apparatus is first acquired. Next, a control point on a contour figure included in the mask shape, a function form of polynomial parameterization, and an order of the function form are acquired. It should be noted that hereinbelow, the “order” refers to an order of a function form unless stated to the contrary. Next, the contour figure is Fourier-transformed using the polynomial parameterization based on the control point, the function form, and the order to predict (simulate) a resist pattern. This causes the mask shape to be represented as an interpolation curve so that the amount of data can be reduced, enabling the curve to be directly Fourier-transformed. As a result, the mask shape can be simulated as being a curved shape.

Moreover, the order is a second order or higher. This allows the curve to be represented by polynomial parameterization. A higher order makes it possible to represent a more complicated curve. However, since a higher order requires a higher computing power, the order may be in a range from the second order to a third order.

In a case where the order is a second order, an error function, an imaginary error function, a complementary error function, or a complementary imaginary error function is used to perform the Fourier transform of the contour figure.

In a case where the order is a third order, the Fourier transform of the contour figure is performed by a numerical integration. This is because an antiderivative needs to be calculated. It should be noted that the above-described Gauss-Legendre quadrature is not limiting and any other numerical integration such as a simplex method may be used. However, in a case where the Gauss-Legendre quadrature is used, it is possible to perform the numerical integration with a less calculation load and a higher accuracy.

Moreover, the control point, which refers to minimum coordinates for representing the curve, is to be inputted to a simulator by a user. (Expression 6) and (Expression 7) are functions that perform interpolation between control points. A function form of a function that performs interpolation between control points and the order of the function form are to be inputted to the simulator by the user. The simulator includes an arithmetic device such as a Central Processing Unit (CPU). The arithmetic device acquires a designed pattern, acquires the inputted control point, function form, and order, and performs the Fourier transform.

Moreover, prior to the acquiring of the control point, the function form, and the order, a first mode in which the contour figure is to be Fourier-transformed using the polynomial parameterization may become selectable by the user. It should be noted that in addition to the first mode, a method similar to that of the comparative example described with reference to FIG. 4 may also become selectable. The simulator may further include a display controller that causes a display device such as a display to display a content. The display controller causes the display device to display a User Interface (UI) through which the user is able to select the first mode.

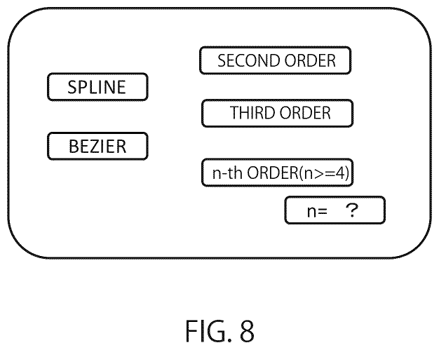

FIG. 8 is a diagram illustrating an example of a displayed content on the display device.

In a case where a Spline curve is to be selected as the parametric representation, the user presses a “SPLINE” button. In a case where a Bezier curve is to be selected as the parametric representation, the user presses a “BEZIER” button. In a case where a second order is to be selected, the user presses a “SECOND ORDER” button. In a case where a third order is to be selected, the user presses a “THIRD ORDER” button. In a case where fourth or higher order is to be selected, the user presses an “n-th ORDER (n>=4)” button and enters the order in an “n=?” entry field.

Moreover, in a case where the first mode is selected, the control point, the function form, and the order may be acquired. The arithmetic device acquires the control point, the function form, and the order, for example, after acquiring an input (information) indicating that the first mode is selected.

It should be noted that the first mode may become selectable by the user before the Fourier transform is performed.

Moreover, the lithography simulation method according to the present embodiment may be included in a process of an optical proximity effect correction method or a method of manufacturing a semiconductor apparatus or may be an independent process (for example, Step S30 in FIG. 1). In the optical proximity effect correction method, after the prediction of a resist pattern, the correction of the pattern of the mask substrate and the prediction of the resist pattern are repeatedly performed until the predicted resist pattern has a desired shape.

At least a part of the lithography simulation method and the optical proximity effect correction method according to the present embodiment may be implemented by hardware or implemented by software. In a case where it is implemented by software, a program that implements a function of at least the part of the lithography simulation method and the optical proximity effect correction method may be stored in a recording medium such as a flexible disk or a CD-ROM to be read and executed by a computer. The recording medium is not limited to a removable medium such as a magnetic disk or an optical disk and may be a fixed recording medium such as a hard disk apparatus or a memory. Moreover, the program that implements the function of at least the part of the lithography simulation method and the optical proximity effect correction method may be distributed through communication lines (including wireless communication) such as the Internet. Further, the program may be distributed in a coded, modulated, or compressed state through a wired circuit or a wireless circuit, such as the Internet, or distributed as stored in a recording medium.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A lithography simulation method comprising:
acquiring a mask shape to be transferred from a mask substrate to a wafer substrate using a projection exposure apparatus;
acquiring a control point on a contour figure included in the mask shape, a function form of polynomial parameterization, and an order of the function form; and
Fourier-transforming the contour figure using the polynomial parameterization based on the control point, the function form, and the order to predict a resist pattern.

2. The lithography simulation method according to claim 1, wherein the function form is a parametric spline curve or a Bezier curve.

3. The lithography simulation method according to claim 1, wherein the order is a second order or higher.

4. The lithography simulation method according to claim 3, wherein the order is in a range from the second order to a third order.

5. The lithography simulation method according to claim 1, wherein the Fourier-transforming of the contour figure includes transforming a double integration into a single integration by Green's theorem to Fourier-transform the contour figure.

6. The lithography simulation method according to claim 1, wherein
the function form is a parametric spline curve or a Bezier curve,
the order is a second order, and
the Fourier-transforming of the contour figure includes Fourier-transforming the contour figure using an error function, an imaginary error function, a complementary error function, or a complementary imaginary error function.

7. The lithography simulation method according to claim 1, wherein
the function form is a parametric spline curve or a Bezier curve,
the order is a third order, and
the Fourier-transforming of the contour figure includes Fourier-transforming the contour figure by a numerical integration that uses a Gauss-Legendre quadrature.

8. The lithography simulation method according to claim 7, wherein an order of a Legendre polynomial of the Gauss-Legendre quadrature is set in accordance with a phase variation of an integrand in an integral interval.

9. The lithography simulation method according to claim 1, further comprising causing, prior to the acquiring of the control point, the function form, and the order, a first mode in which the contour figure is to be Fourier-transformed using the polynomial parameterization to be selectable.

10. The lithography simulation method according to claim 9, wherein the acquiring of the control point, the function form, and the order includes acquiring, in response to the first mode being selected, the control point, the function form, and the order.

11. The lithography simulation method according to claim 2, wherein the order is a second order or higher.

12. The lithography simulation method according to claim 11, wherein the order is in a range from the second order to a third order.

13. An optical proximity effect correction method comprising:
acquiring a mask shape to be transferred from a mask substrate to a wafer substrate using a projection exposure apparatus;
acquiring a control point on a contour figure included in the mask shape, a function form of polynomial parameterization, and an order of the function form;
Fourier-transforming the contour figure using the polynomial parameterization based on the control point, the function form, and the order to predict a resist pattern; and
repeating correcting a pattern of the mask substrate and predicting the resist pattern until the predicted resist pattern has a desired shape.
